(19) United States
(12) Patent Application Publication
(10) Pub. No.: US 2004/0051162 A1
(43) Pub. Date: Mar. 18, 2004

(54) Structure and method of providing reduced programming voltage antifuse

(75) Inventors: Dureseti Chidambarrao, Weston, CT (US); Ulrich Frey, Poughkeepsie, NY (US); Suryanarayan G. Hegde, New York, NY (US); William Robert Tonti, Essex Junction, VT (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignees: INTERNATIONAL BUSINESS MACHINES CORPORATION, ARMONK, NY; Infineon Technologies North America Corp.

(21) Appl. No.: 10/243,540

(22) Filed: Sep. 13, 2002

(51) Int. Cl. H01L 29/00

(52) U.S. Cl. 257/530

(57) ABSTRACT

As disclosed herein, a structure and method is provided for forming an integrated circuit including a reduced programming voltage antifuse on a semiconductor substrate. The method includes doping a portion of a semiconductor substrate with nitrogen and a charge carrier dopant source, and forming a thin dielectric over the doped portion of the semiconductor substrate, wherein the thin dielectric is subject to breakdown upon application of a breakdown voltage. The method further includes forming a first conductor separated from the semiconductor substrate by the thin dielectric, and forming a second conductor conductively coupled to the doped portion of the semiconductor substrate.

### FIELD OF THE INVENTION

The present invention relates to semiconductor processing, and more specifically to a structure and method for fabricating an antifuse for operating at a reduced programming voltage.

### BACKGROUND OF THE INVENTION

Electrically operable fuses are utilized within the field of integrated circuit devices and processes for a number of purposes, including programming alterable circuit connections, or replacing defective circuit elements with redundant circuit elements. As one type of electrically operable fuse, a so-called “antifuse” is a device having two conductors and an intervening dielectric layer, where the dielectric layer is subject to breakdown upon application of sufficient voltage and current to the conductors. The resistance across the dielectric layer of the antifuse encodes the “on” or “off” state of the antifuse.

A typical (pre-breakdown) “off” resistance for antifuses having a dielectric layer of silicon nitride (SiN), “gate oxide”, i.e. silicon dioxide (SiO2) formed by the gate oxide forming process, or silicon oxide-silicon oxynitride-silicon oxide (ONO) is more than 1 GΩ. After breakdown, resistance across the dielectric layer is measurably lower, indicating the “on” state. Thus, the on-off state of the antifuse is read using a resistance measuring circuit.

At present, a high voltage and a current of several milliamperes may be required to adequately break down the dielectric of antifuses on an integrated circuit. Such required high currents impose minimum size constraints on the antifuses and wiring thereto, thereby requiring significant integrated circuit area to implement, while also negatively affecting the flow of production testing and repair of new chips. Provisions must also be made to safeguard the integrated circuit from being negatively affected by the required high programming voltage. The high programming voltage may give rise to concerns for electrostatic discharge protection (ESD) and the reliability of the integrated circuit.

In order for the state of an antifuse to be reliably read, the post-breakdown resistance must be in the megaohm range or below and, for yield reasons, this must be achieved for virtually all of the antifuses on the integrated circuit. Gate oxide antifuses typically require currents in the several milliampere range to achieve such post-breakdown resistance. However, such currents and the required high voltage are close to integrated circuit design constraints based on ESD protection and reliability considerations.

### SUMMARY OF THE INVENTION

According to an aspect of the invention, a structure and method is provided for forming an integrated circuit including a reduced programming voltage antifuse on a semiconductor substrate. The method includes doping a portion of a semiconductor substrate with nitrogen and a charge carrier dopant source, and forming a thin dielectric over the doped portion of the semiconductor substrate, wherein the thin dielectric is subject to breakdown upon application of a breakdown voltage. The method further includes forming a first conductor separated from the semiconductor substrate by the thin dielectric, and forming a second conductor conductively coupled to the doped portion of the semiconductor substrate.

Preferably, the thin dielectric of the antifuse incorporates some of the nitrogen from the doped portion of the semiconductor substrate. The doping is preferably performed with a ratio of charge carrier dopant source to nitrogen of between about 0.5:1 and about 1.3:1. More preferably, doping is performed with a ratio of the charge carrier dopant source to nitrogen of about 1:1. In addition, the doping is preferably performed by ion implantation. When implanted, the preferred concentration of ions is between about 1×10E14 and 1×10E17 carriers per cm3. The charge carrier dopant source is further preferably selected from the group consisting of: arsenic (As), phosphorous (P), indium (In), antimony (Sb) and boron (B).

According to a preferred embodiment of the invention, ion implants of nitrogen and a charge carrier dopant source into the semiconductor substrate for the antifuse are performed using the same mask that is used to perform ion implants for decoupling capacitors into another portion of the substrate.

According to another aspect of the invention, an integrated circuit is provided including an antifuse of the type having a semiconductor substrate, a first conductor separated from the semiconductor substrate by a thin dielectric wherein the thin dielectric is subject to breakdown upon application of a breakdown voltage, and a second conductor conductively coupled to the semiconductor substrate, wherein the semiconductor substrate is doped with nitrogen and a charge carrier dopant source prior to forming the thin dielectric.

### BRIEF DESCRIPTION OF THE DRAWINGS

FIG. 1 illustrates post-breakdown resistance measurements taken for antifuses fabricated with different amounts of nitrogen and charge carrier dopants.

FIG. 2 illustrates changes in antifuse breakdown voltages observed for different ratios of charge carrier dopants to nitrogen implants.

FIG. 3 illustrates distributions of post-breakdown resistance observed for different oxide dielectric thicknesses of antifuses.

FIG. 4 illustrates an antifuse fabricated according to a preferred embodiment of the invention.

FIG. 5 illustrates a deep trench decoupling capacitor in which an implant is performed through the same mask used to make implants into an antifuse as illustrated in FIG. 4.

### DETAILED DESCRIPTION OF THE PREFERRED EMBODIMENTS

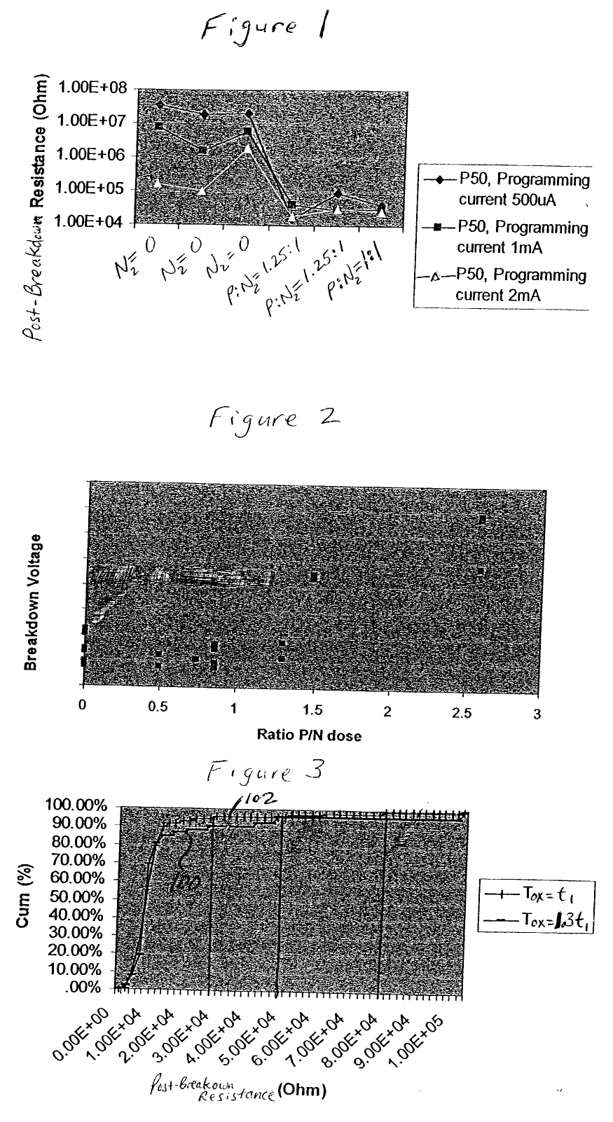

The intentional doping of the semiconductor substrate with a high amount of charge carriers and nitrogen prior to forming a thin dielectric of silicon dioxide thereon tends to lower the post-breakdown resistance and the voltage required voltage to program the fuse (the “breakdown voltage”). The inventors have observed a lowering of the post-breakdown resistance and/or lowering of the breakdown voltage of the antifuse when charge carrier dopants are increased to a level of about 5×10¹⁴ cm⁻² and have observed this up to a level of 1×10¹⁷ cm⁻² as well. Thus, as shown in FIG. 1, post-breakdown resistance measurements of six antifuse samples are shown, three in which region 28 was not intentionally doped with nitrogen (N2), and three in which region 28 was doped with nitrogen and a charge carrier dopant source (in this case phosphorous) at ratios of 1:1 or 1.25:1. The antifuse samples were also tested at different levels of programming current, 0.5 mA, 1 mA and 2 mA. As evident from FIG. 1, the antifuse samples that were doped with nitrogen each had a decrease in post-breakdown resistance of about two orders of magnitude.

As further shown in FIG. 2, the ratio of the charge carrier dopant source such as phosphorous to nitrogen affects the resulting breakdown voltage of the thin dielectric. If the ratio is too high, a jump in breakdown voltage results. A jump in breakdown voltages were observed for ratios of phosphorous to nitrogen of 1.5:1 and greater, while significantly lower breakdown voltages were observed for P:N2 ratios of 1.3:1 and below.

It was also observed when a semiconductor substrate of silicon is doped only with additional charge carriers, the oxidation rate for growing an oxide dielectric increases, as compared to a substrate that is not so heavily doped. Thus, when the oxide dielectric of the antifuse is grown over a heavily doped region of the substrate at the same time as the gate oxide is grown of other devices, an antifuse dielectric results that is significantly thicker than the gate oxide which is formed over not so heavily doped portions of the substrate. A thicker antifuse dielectric is not desirable because it may require a higher voltage to break down. However, when the substrate is both doped with additional charge carriers and also with nitrogen, the oxide dielectric of the antifuse does not become too thick, because nitrogen retards the growth rate of the oxide.

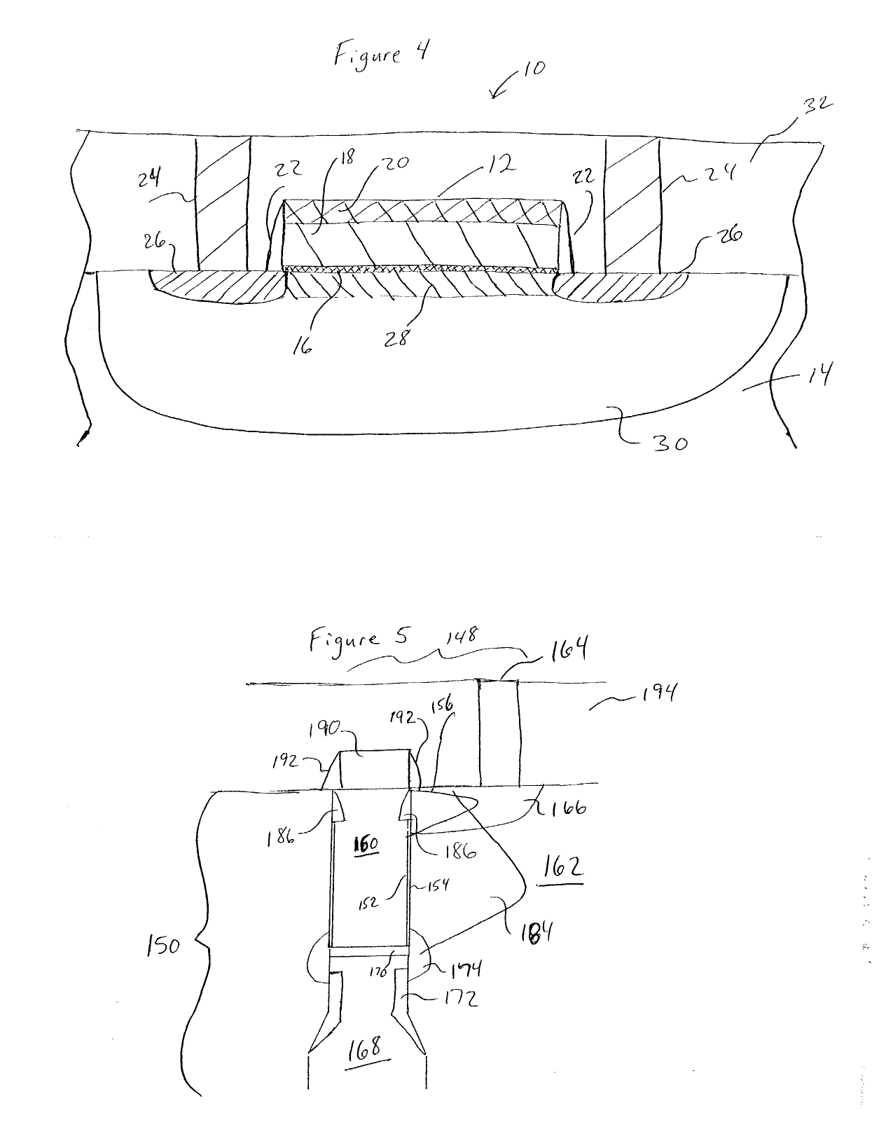

As illustrated in FIG. 3, reduction in the oxide thickness alone does not lead to an acceptable distribution of the post-breakdown resistance of antifuses. For the curves shown in FIG. 3, the post-breakdown distributions 100, 102 of resistance is shown for oxide dielectrics which vary in thickness but which are both programmed by the same voltage and current. Distribution 102 is for an oxide dielectric grown over a portion of a substrate implanted with nitrogen. Distribution 100 is for an oxide dielectric grown over an unimplanted portion of the substrate. Implanting of nitrogen alone, while decreasing the oxide dielectric thickness itself, does not adequately change the distribution of the post-breakdown resistance. Rather, referring to FIG. 1 again, both the addition of nitrogen and additional charge carriers are needed in order to achieve a step change downward in the post-breakdown resistance of the antifuse oxide dielectric.

FIG. 4 illustrates a first embodiment of an antifuse according to the invention. As illustrated in FIG. 4, antifuse 10 includes a first conductor 12 which is separated from a semiconductor (preferably silicon) substrate 14 by a thin dielectric 16. Preferably the first conductor includes a layer 18 of deposited polysilicon, and further includes a layer 20 of metal or metal silicide. Spacers 22 may be formed on sidewalls of the first conductor 12. At least one second conductor 24 is conductively coupled to the semiconductor substrate 14, preferably to a doped region 26 of the substrate 14. The substrate 14 includes a region 28 which is doped with nitrogen and a charge carrier dopant source prior to forming the thin dielectric 16.

One example of a process for fabricating an antifuse illustrated in FIG. 4 is as follows. For an n-type conduction antifuse in which the dominant charge carriers are electrons, an intrinsic, n− type or p− type substrate 14 is used, in which an n type well 30 is formed therein, as by implantation of a dopant such as phosphorous (P), although arsenic (As) and antimony (Sb) are suitable alternatives. Wells are usually implanted after the separation of substrate surface areas into active area and isolations (e.g. shallow trench isolations), which serve to isolate nearby conducting areas of the substrate from each other. Then, a mask is applied to the substrate, and region 28 is doped, preferably by ion implantation, with nitrogen (N2) and an n-type charge carrier dopant source preferably phosphorous, but also possible As, or Sb. An additional mask may be applied, and region 28 further doped with N2 to increase the amount of nitrogen present, relative to the charge carrier dopant source. The thin dielectric 16 is then formed, as by local oxidation of silicon or deposition of a gate oxide. Thereafter, first conductor 12 is formed, by depositing a layer of n+ doped polysilicon 18 followed by formation of a silicide layer 20, patterning of the resulting stack and forming of optional spacers 22. Alternatively, in place of silicide 20, a barrier layer such as tungsten nitride (WN), and a metal layer 20 of tungsten may be deposited, and patterned. Thereafter, n+ implants are made to one or more regions 26 to provide conduction, after breakdown of dielectric 16, between first conductor 12 and the second conductor 24. Second conductor 24 is formed, after deposition of an interlevel dielectric 32, by etching a contact hole therethrough and depositing a suitable conductor, which may be for example, a highly doped polysilicon, or a refractory metal such as tungsten.

Alternatively, for a p-type conduction antifuse in which the dominant charge carriers are holes, an intrinsic, n− type or p− type substrate 14 is used, in which an p type well 30 is formed therein, as by implantation of a dopant such as boron (B), although indium (In) is a suitable alternative. All other process steps are as described above, except that each time doping is done, a p type charge carrier dopant source is used. Thus, region 28 is doped with nitrogen and a charge carrier dopant such as boron or indium. Further, first conductor 12 is doped p+ with boron or indium, and regions 26 are also doped p+ using boron or indium.

In a preferred embodiment of the invention, nitrogen and dopant implants into a region 28 (FIG. 4) of the substrate for an antifuse are done through a single mask that is simultaneously used for making implants for deep trench type decoupling capacitors in another part of the substrate. FIG. 5 illustrates the structure of a deep trench decoupling capacitor 148. In the fabrication of such decoupling capacitor, an n+ dopant implant must be made into the substrate (resulting in dopant profile 184) to create a conductive path from a diffusion 166 at the substrate surface to the trench capacitor 168. Such implant requires the use of a mask that blocks most areas of the substrate, but which is open where such decoupling capacitors are to be formed. This embodiment takes advantage of that already used mask to do the required implants into region 28 of the antifuse (FIG. 4). Note that when the required implants are made into region 28 (FIG. 4), in the decoupling capacitor a dopant profile 156 results from such implants. The implanted dopant profile 156 does not adversely affect the operation of the decoupling capacitor so long as the following constraint is observed, that the dopant type of profile 156 has the same polarity as the dopant type of the decoupling capacitor implant 184, i.e. both n+ or both p+.

While the invention has been described herein in accordance with certain preferred embodiments thereof, those skilled in the art will recognize the many modifications and enhancements which can be made without departing from the true scope and spirit of the present invention, limited only by the claims appended below.

What is claimed is:

1. A method of forming an integrated circuit including an antifuse on a semiconductor substrate, comprising:
doping a portion of a semiconductor substrate with nitrogen and a charge carrier dopant source;
forming a thin dielectric over said doped portion of said semiconductor substrate;
forming a first conductor separated from said semiconductor substrate by said thin dielectric;
forming a second conductor conductively coupled to said doped portion of said semiconductor substrate,
said thin dielectric being subject to breakdown upon application of a breakdown voltage.

2. The method of claim 1 wherein said thin dielectric incorporates some of said nitrogen from said doped portion.

3. The integrated circuit of claim 1 wherein said doping is performed with a ratio of said charge carrier dopant source to said nitrogen of between about 0.5:1 and about 1.3:1.

4. The integrated circuit of claim 3 wherein said doping is performed with a ratio of said charge carrier dopant source to said nitrogen of about 1:1.

5. The method of claim 1 wherein said second conductor is conductively coupled to said doped portion of said semiconductor substrate through a second portion of said semiconductor substrate not doped with said nitrogen.

6. The method of claim 1 wherein said doping is performed by ion implantation.

7. The method of claim 4 wherein said doping is performed so as to provide an implanted concentration of ions of between about 1×10E14 and 1×10E17 carriers per cm3.

8. The method of claim 1 wherein said charge carrier dopant source is selected from the group consisting of: arsenic (As), phosphorous (P), indium (In), antimony (Sb) and boron (B).

9. The method of claim 1 wherein said doping is performed by implantation through a mask, wherein said mask is also used for implanting dopants into capacitors on said substrate.

10. An integrated circuit including an antifuse of the type comprising a semiconductor substrate, a first conductor separated from said semiconductor substrate by a thin dielectric wherein said thin dielectric is subject to breakdown upon application of a breakdown voltage, and a second conductor conductively coupled to said semiconductor substrate, wherein said semiconductor substrate is doped with nitrogen and a charge carrier dopant source prior to forming said thin dielectric.

11. The integrated circuit of claim 10 wherein said semiconductor substrate is doped with a ratio of said charge carrier dopant source to said nitrogen of between about 0.8:1 and 1.3:1.

12. The integrated circuit of claim 11 wherein said semiconductor substrate is doped with a ratio of said charge carrier dopant source to said nitrogen of about 1:1.

13. The integrated circuit of claim 10 wherein said semiconductor substrate is doped to provide an implanted concentration of ions of between about 1×10E14 and 1×10E17 carriers per cm³.

14. The method of claim 13 wherein said charge carrier dopant source is selected from the group consisting of: arsenic (As), phosphorous (P), indium (In), antimony (Sb) and boron (B).
